(19) United States
(12) Patent Application Publication
(10) Pub. No.: US 2023/0275072 A1
(43) Pub. Date: Aug. 31, 2023

(54) LIGHT-EMITTING DEVICE

(71) Applicant: QUANZHOU SANAN SEMICONDUCTOR TECHNOLOGY CO., LTD., Quanzhou (CN)

(72) Inventors: Wenhua BAI, Quanzhou (CN); Shunyi CHEN, Quanzhou (CN); Senpeng HUANG, Quanzhou (CN); Jian LIU, Quanzhou (CN); Changchin YU, Quanzhou (CN); Weng-Tack WONG, Quanzhou (CN); Chen-ke HSU, Quanzhou (CN)

(21) Appl. No.: 18/186,817

(22) Filed: Mar. 20, 2023

Related U.S. Application Data
(63) Continuation-in-part of application No. PCT/CN2021/095854, filed on May 25, 2021.

(51) Int. Cl. H01L 25/075; H01L 33/56; H01L 33/12

(52) U.S. Cl. CPC H01L 25/0753; H01L 33/56; H01L 33/12

(57) ABSTRACT

A light-emitting device includes a substrate, first and second chips, a first buffer layer, and an encapsulating layer. The substrate includes first and second surfaces opposite to each other. Each of the first and second chips is disposed on the first surface of the substrate, and is formed with top and bottom surfaces opposite to each other and side surfaces that are connected to the top surface and the bottom surface. The first buffer layer is disposed on the top surface of the second chip. The substrate has two edges spaced apart from each other in one of a first direction and a second direction. Each of the first and second chips has a minimum distance distant from one of the two edges in one of the two directions. Another light-emitting device is also disclosed.

### CROSS-REFERENCE TO RELATED APPLICATION

This application is a bypass continuation-in-part (CIP) application of PCT International Application No. PCT/CN2021/095854, filed on May 25, 2021. The entire content of the International application is incorporated herein by reference.

### FIELD

The disclosure relates to a semiconductor device, and more particularly to a light-emitting device.

### BACKGROUND

Light-emitting diode (LED) chip has been rapidly developed because of its excellent performance. The ultraviolet LED (UV LED), especially the deep ultraviolet LED (DUV LED), has great application value, particularly in sterilization and disinfection, and hence, drawing a great deal of attention and becoming a new research focus.

A conventional DUV LED packaging structure mainly includes a bowl-shaped ceramic carrier substrate, and a quartz-glass packaging body disposed on the bowl-shaped ceramic carrier substrate. Since the bowl-shaped ceramic carrier substrate is formed with a cavity for receiving an LED chip and has a certain thickness, the conventional DUV LED packaging structure has disadvantages of large size and high cost. In addition, due to not having a refractive index that changes in a gradient manner when a light emitted from the LED chip initially passes from its substrate (such as a sapphire substrate with a refractive index of about 1.76) into the air (present in a space between the bowl-shaped ceramic carrier substrate and the quartz-glass packaging body and generally considered to have a refractive index of 1), and then into the quartz-glass packaging body (with a refractive index of about 1.4), the light emitting efficiency of the conventional DUV LED packaging structure is low.

In addition, there is another form of the DUV LED packaging structure which includes a planar ceramic substrate and a molded silicone rubber covering a chip disposed on the planar ceramic substrate. However, a major drawback of this packaging structure is that a DUV light (having a wavelength of 290 nm or less) is highly destructive to the molded silicone rubber and cracks are prone to occur in the molded silicone rubber under prolonged exposure to this radiation. Moreover, the molded silicone rubber has a relatively low transmittance to the DUV light. Furthermore, the molded silicone rubber may release stress during aging, which can directly affect the chip and even cause the chip to be pulled out (i.e., the chip is separated from the ceramic substrate), causing a reduce of the reliability of the DUV LED packaging structure.

### SUMMARY

Therefore, an object of the disclosure is to provide a light-emitting device that can alleviate at least one of the drawbacks of the prior art.

According to one aspect of the disclosure, the light-emitting device includes a substrate, a first chip, a second chip, a first buffer layer, and an encapsulating layer.

The substrate includes a first surface and a second surface opposite to the first surface. The first surface extends along a first direction and a second direction intersecting the first direction.

The first chip is disposed on the first surface of the substrate, and includes a first type semiconductor layer, a second type semiconductor layer, and an active layer that is interposed between the first type semiconductor layer and the second type semiconductor layer and that is configured to emit a light.

The second chip is disposed on the first surface of the substrate, and is formed with a top surface, a bottom surface opposite to the top surface, and a plurality of side surfaces that are connected to the top surface and the bottom surface.

The first buffer layer is disposed on the top surface of the second chip so as to relieve stress.

The encapsulating layer is made of fluorine-containing resin and disposed on the first surface of the substrate to allow the first chip, the first buffer layer and the second chip to be encapsulated between the substrate and the encapsulating layer.

The substrate has two edges spaced apart from each other in one of the first direction and the second direction. The first chip has a first minimum distance distant from one of the two edges in one of the first direction and the second direction. The second chip has a second minimum distance distant from one of the two edges in the corresponding one of the first direction and the second direction. The first minimum distance is greater than the second minimum distance.

According to another aspect of the disclosure, the light-emitting device includes a substrate, a first chip, a second chip, a first buffer layer, and an encapsulating layer.

The substrate includes a first surface, and a second surface opposite to the first surface. The first surface defines a vertical direction perpendicular thereto.

The first chip is disposed on the first surface of the substrate, and includes a first type semiconductor layer, a second type semiconductor layer, and an active layer that is interposed between the first type semiconductor layer and the second type semiconductor layer and that is configured to emit a light.

The second chip is disposed on the first surface of the substrate, and is formed with a top surface, a bottom surface opposite to the top surface, and a plurality of side surfaces that are connected to the top surface and the bottom surface.

The first buffer layer is disposed on the top surface of the second chip so as to relieve stress.

The encapsulating layer is made of fluorine-containing resin and disposed on the first surface of the substrate to allow the first chip, the first buffer layer and the second chip to be encapsulated between the substrate and the encapsulating layer.

Each of the first chip and the second chip has a thickness in the vertical direction, and the thickness of the first chip is greater than that of the second chip.

### BRIEF DESCRIPTION OF THE DRAWINGS

Other features and advantages of the disclosure will become apparent in the following detailed description of the embodiments with reference to the accompanying drawings. It is noted that various features may not be drawn to scale.

FIG. 1 is a cross-sectional schematic view illustrating a first embodiment of a light-emitting device according to the disclosure.

FIG. 2 is a top schematic view illustrating the light-emitting device of FIG. 1, in which a first buffer layer and an insulating layer are not shown.

FIG. 3 is a cross-sectional schematic view illustrating a variation of the first embodiment of the light-emitting device according to the disclosure.

FIG. 4 is a cross-sectional schematic view illustrating another variation of the first embodiment of the light-emitting device according to the disclosure.

FIG. 5 is a cross-sectional schematic view illustrating yet another variation of the first embodiment of the light-emitting device according to the disclosure.

FIG. 6 is a top schematic view illustrating the light-emitting device of FIG. 5, in which the first buffer layer, a second buffer layer, and the encapsulating layer are omitted.

FIG. 7 is a top schematic view illustrating still yet another variation of the first embodiment of the light-emitting device according to the disclosure, in which the first and second buffer layers and the encapsulating layer are omitted.

FIG. 8 is a top schematic view illustrating still yet another variation of the first embodiment of the light-emitting device according to the disclosure, in which the first and second buffer layers and the encapsulating layer are omitted.

FIG. 9 is a cross-sectional schematic view illustrating a second embodiment of the light-emitting device according to the disclosure.

FIG. 10 is a top schematic view illustrating the light-emitting device of FIG. 9, in which the first buffer layer and the encapsulating layer are omitted.

FIG. 11 is a cross-sectional schematic view illustrating a variation of the second embodiment of the light-emitting device according the disclosure.

FIG. 12 is a cross-sectional schematic view illustrating another variation of second embodiment of the light-emitting device according to the disclosure.

FIG. 13 is a cross-sectional schematic view illustrating yet another variation of the second embodiment of the light-emitting device according to the disclosure.

FIG. 14 is a cross-sectional schematic view illustrating still yet another variation of the second embodiment of the light-emitting device according to the disclosure.

FIG. 15 is a cross-sectional schematic view illustrating still yet another variation of the second embodiment of the light-emitting device according to the disclosure.

FIG. 16 is a cross-sectional schematic view illustrating still yet another variation of the second embodiment of the light-emitting device according to the disclosure.

FIG. 17 is a cross-sectional schematic view illustrating still yet another variation of the second embodiment of the light-emitting device according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

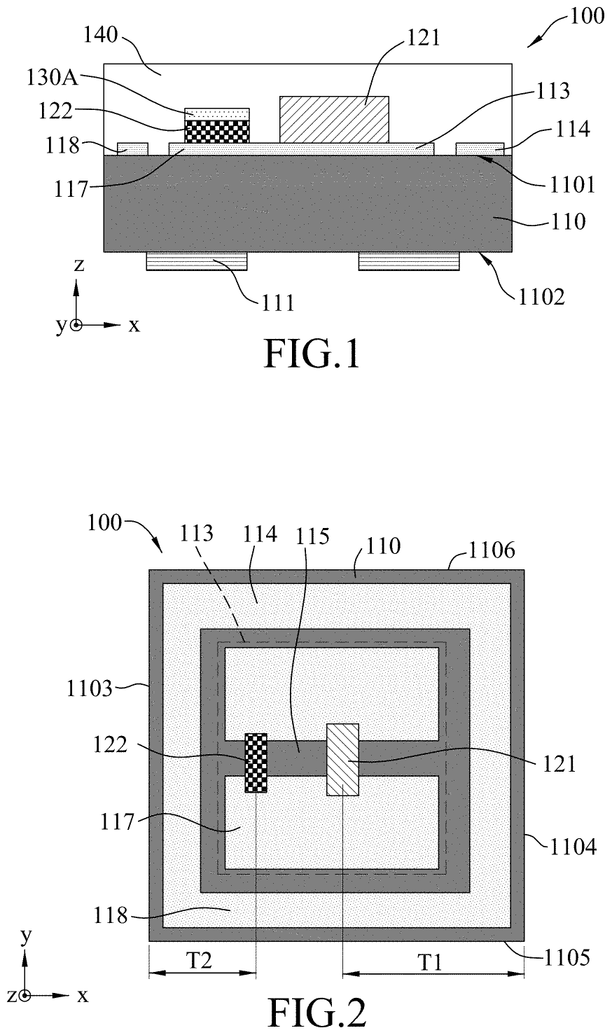

Referring to FIG. 1, a first embodiment of a light-emitting device 100 according to the disclosure includes a substrate 110 including a first surface 1101 and a second surface 1102 opposite to the first surface 1101, a first chip 121 disposed on the first surface 1101 of the substrate 110, a second chip 122 disposed on the first surface 1101 of the substrate 110, a first buffer layer 130A disposed on the top surface of the second chip 122 so as to relieve stress, and an encapsulating layer 140 made of fluorine-containing resin and disposed on the first surface 1101 of the substrate 110 to allow the first chip 121, the first buffer layer 130A and the second chip 122 to be encapsulated between the substrate 110 and the encapsulating layer 140.

As shown in FIG. 1, the first surface 1101 of the substrate 110 extends along a first direction X and a second direction Y intersecting the first direction X, and defines a vertical direction Z perpendicular thereto.

In some embodiments, the first surface 1101 of the substrate 110 is rectangular. In other embodiments, the first surface 1101 is square (i.e., a width of the first surface 1101 along the first direction X is equal to that along the second direction Y). However, the shape of the first surface 1101 is not limited thereto.

In this embodiment, the substrate 110 includes a material having excellent mechanical strength, heat dissipation, insulation, etc. In addition, the substrate 110 may include a material having a high thermal conductivity. Moreover, the substrate 110 may be made of a material having good heat dissipation properties so that heat generated from the first and second chips 121, 122 can be effectively discharged to the outside. In an exemplary embodiment, the substrate 110 includes an insulating material, for example, a ceramic material such as a low temperature co-fired ceramic (LTCC) or a high temperature co-fired ceramic (HTCC). In another exemplary embodiment, the substrate 110 includes a high heat resistant material, for example, a thermoset resin, such as a silicone resin, an epoxy resin, or the like. In yet another exemplary embodiment, the substrate 110 includes a metal compound. For instance, the package substrate 110 may include a metal oxide having a thermal conductivity equal to or greater than 140 W/mK. The metal compound may be, for example, aluminum nitride (AlN) or aluminum oxide (Al₂O₃).

Referring to FIGS. 1 and 2, in an exemplary embodiment, the first surface 1101 of the substrate 110 has a functional section 113 and a non-functional section 114 that surrounds the functional section 113. In addition, a plurality of electrode pads 111 are disposed on the second surface 1102 to be electrically connected to the functional section 113. In another exemplary embodiment, the first and second chips 121, 122 are located within the functional section 113, and may be connected to the functional section 113 via, for instance, a gold wire or directly soldered to the functional section 113. In yet another exemplary embodiment, the light-emitting device 100 further includes a first metal layer 117 that is disposed on the functional section 113 of the first surface 1101 of the substrate 110 and between the first and second chips 121, 122 and the first surface 1101 of the substrate 110. The first metal layer 117 is formed with a spacing 115 to form two electrical isolation areas. In addition, one of the two electrical isolation areas is connected to a positive electrode of each of the first chip 121 and the second chip 122, and the other of the two electrical isolation areas is connected to a negative electrode of each of the first chip 121 and the second chip 122. The positive and negative electrodes of each of the first and second chips 121, 122 located within the functional section 113 may be connected to exterior terminals through the electrode pads 111.

The first chip 121 may be of any type, such as a light-emitting chip emitting an invisible light having a wavelength ranging from 200 nm to 380 nm. Specifically, the invisible light may have a long wavelength (from 315 nm to 380 nm), a medium wavelength (from 290 nm to 315 nm), or a short wavelength (from 200 nm to 290 nm). The wavelength of the invisible light may be selected based on actual needs, such as for surface sterilization or for surface curing.

There may be a plurality of the first chips 121 disposed on the first surface 1101, and the number of the first chips 121 may depend on requirements such as a work function. In addition, the light-emitting device 100 may have different types of the first chips 121 each of which emits invisible light having a wavelength different from that of the other based on different applications. In this embodiment, the first chip 121 emits a light having a wavelength of less than 290 nm.

In certain embodiments, the first chip 121 emits a light having a wavelength which falls within a range of 780 nm to 1000 nm, also known as the wavelength of an infrared light.

While not shown in detail, it may be comprehensible that the first chip 121 may include a base and a semiconductor structure disposed on a surface of the base. The semiconductor structure includes a first type semiconductor layer (n-type semiconductor layer), an active layer, and a second type semiconductor layer (p-type semiconductor layer) sequentially formed on the surface of the base. Each of the n-type semiconductor layer, the active layer, and the p-type semiconductor layer may include a Group III-V compound, e.g., an aluminum gallium indium nitride ((AlGaIn)N). The n-type semiconductor layer may be a conductive semiconductor layer including an n-type impurity such as silicon (Si), and the p-type semiconductor layer may be a conductive semiconductor layer including a p-type impurity such as magnesium (Mg). The active layer is interposed between the first- and second-type semiconductor layers, and may include a multiple quantum well (MQW) structure. Moreover, by controlling the structure and composition of the MQW structure, a light having a desired peak wavelength can be obtained. The first chip 121 includes, as mentioned above, the positive electrode and the negative electrode respectively connected to the p-type semiconductor layer and the n-type semiconductor layer. In addition, the positive electrode and the negative electrode of the first chip 121 are connected to the functional section 113 of the substrate 110 by, for example, soldering, eutectic, or the like, thereby achieving the fixation of the first chip 121. The positive electrode and the negative electrode of the first chip 121 are electrically connected to the exterior terminals through the electrode pads 111 disposed on the second surface 1102 of the substrate 110.

The second chip 122 may be an electrostatic discharge protection chip, such as a Zener diode, which can be used to avoid damage to the first chip 121 due to an electrostatic charge caused by an external power supply. In this embodiment, the electrostatic discharge protection chip serving as the second chip 122 is located within the functional section 113 of the first surface 1101 of the substrate 110, and is connected in anti-parallel with the first chip 121. The second chip 122 may control a current flow and a voltage level within a relatively small range during the use of the first chip 121 so as to prevent the first chip 121 from an impact caused by a large current flow and/or a high level of voltage, thereby protecting the first chip 121.

Referring again to FIG. 2, the substrate 110 is rectangular from a top view. The first direction X is orthogonal to the second direction Y, and the substrate 110 has two (first and second) edges 1105, 1106 that extend in parallel along the second direction X and that are spaced apart from each other in the first direction Y, and also two (first and second) edges 1103, 1104 that extend in parallel along the second direction Y and that are spaced apart from each other in the second direction X. In addition, the second chip 122 is located within the functional section 113 adjacent to the first edge 1103 extending along the second direction Y, and the first chip 121 is located within the functional section 113 relatively adjacent to the second edge 1104 extending along the second direction Y. Also, the first chip 121 is distant from the second edge 1104, in the first direction X, by a first minimum distance T1, and the second chip 122 is distant from the first edge 1103, in the first direction X, by a second minimum distance T2. The first minimum distance T1 is greater than the second minimum distance T2. For calculation of the first and second minimum distance T1, T2, a distance between the center point of the first chip 121 and the second edge 1104 extending along the second direction Y, and a distance between the center point of the second chip 122 and the first edge 1103 extending along the second direction Y are selected for measurement.

It should be noted that, in the light-emitting device 100 shown in FIG. 2, the relationship of the first minimum distance T1 and second minimum distances T2 in the first direction X is illustrated. However, in some variations of the embodiments of the light-emitting device 100, the above-mentioned relationship can be applied in the second direction Y.

Referring again to FIGS. 1 and 2, in this embodiment, each of the first chip 121 and the second chip 122 has a thickness in the vertical direction Z, and the thickness of the first chip 121 is greater than that of the second chip 122. In certain embodiments, the thickness of the first chip 121 is greater than that of the second chip 122 by not less than 50 μm. In an exemplary embodiment, the thickness of the first chip 121 is greater than that of the second chip 122 by 50 μm to 300 μm.

The encapsulating layer 140 is made of fluorine-containing resin and disposed on the first surface 1101 of the substrate 110 to allow the first chip 121, the first buffer layer 130A, and the second chip 122 to be encapsulated between the substrate 110 and the encapsulating layer 140. The fluorine-containing resin is an inorganic substance and has a good reliability, i.e., well capable of resisting an ultraviolet radiation. In addition, the fluorine-containing resin may have a refractive index, i.e., n, which ranges from 1.34 to 1.7, and a high transmittance to an ultraviolet light so as to enhance light extraction efficiency of a DUV light-emitting device

However, the adhesion between the fluorine-containing resin and the substrate 110 may be poor. Due to the fluorine-containing resin having a greater coefficient of thermal expansion, the coefficient of thermal expansion of each of the materials of the first chip 121, the second chip 122, and the substrate 110 may seriously mismatch with that of the encapsulating layer 140 made of the fluorine-containing resin. Thus, during a manufacturing process in which the substrate 110 and the encapsulating layer 140 are bonded together under a high-temperature, residual stress may be left inside of the encapsulating layer 140. Furthermore, an intensity difference may exist in part of the interior of the light-emitting device 100 caused by, e.g., different thicknesses and locations of chips (such as the abovementioned first and second chips 121, 122). As a result, during a long-term aging process, the residual stress may be released, generating a crack at the location of the residual stress, resulting in a warpage or a crack at a corner of the encapsulating layer 140. This may cause serious consequences which may further lead to a separation of the encapsulating layer 140 and the substrate 110, causing the chips to be pulled from the substrate 110, particularly for a chip located at the edge of the substrate 110 like the second chip 122 or having a smaller thickness, consequently affecting the reliability of the light-emitting device 100.

Based on the above description, referring back to FIG. 1, each of the first chip 121 and the second chip 122 is formed with a top surface, a bottom surface opposite to the top surface, and a plurality of side surfaces that are connected to the top surface and the bottom surface. The top surface is more distant from the substrate 110 than the bottom surface. The top surface of the first chip 121 may be provided with a light-emitting surface. In addition, the first buffer layer 130A is disposed on the top surface of the second chip 122. By covering the first buffer layer 130A on the top surface of the second chip 122 after disposing the second chip 122 within the functional section 113 of the first surface 1101 of the substrate 110 while prior to bonding the encapsulating layer 140, a contact area between the second chip 122 and the encapsulating layer 140 can be reduced so that the first buffer layer 130A plays a role in relieving the residual stress on the second chip 122 during the aging process of the light-emitting device 100, thereby reducing the risk of the second chip 122 being pulled out.

The first buffer layer 130A may be made from a material selected from the group consisting of silicone rubber, epoxy resin, perfluoropolyether, and combinations thereof, but is not limited thereto. For example, the first buffer layer 130A may be made of silicone rubber covering on the top surface of the second chip 122 by means of dispensing, and an amount of silicone rubber used is determined based on a desired thickness. In certain embodiments, the first buffer layer 130A has a thickness ranging from 10 μm to 200 μm. If the thickness of the first buffer layer 130A is less than 10 μm, there may be less effect on stress buffering. In addition, if the thickness of the first buffer layer 130A is greater than 200 μm, instead of achieving the buffering effect, the encapsulating layer 140 may be prone to cracking. In an exemplary embodiment, the thickness of the first buffer layer 130A ranges from 10 μm to 50 μm.

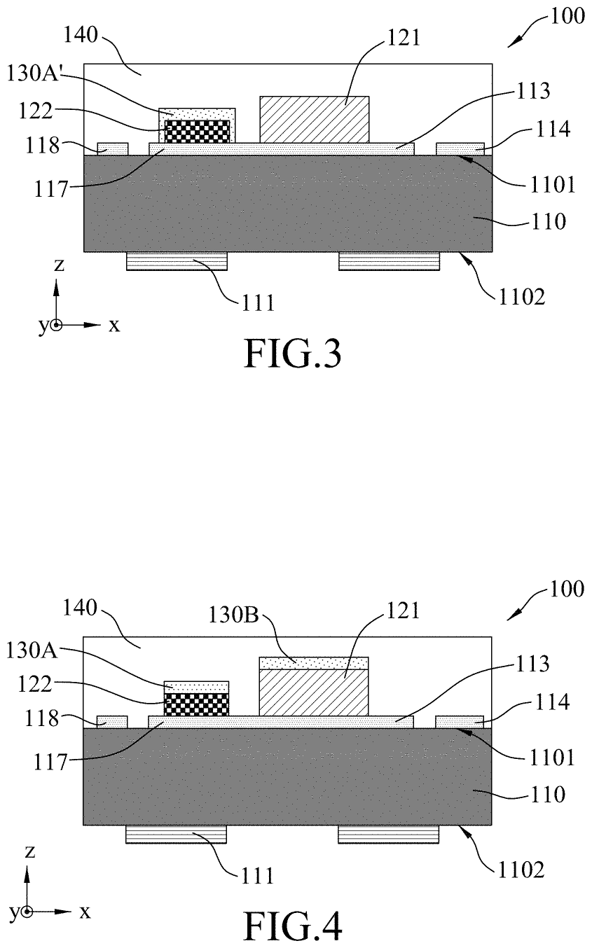

Referring to FIG. 3, in other embodiments, the first buffer layer 130A′ not only covers the top surface of the second chip 122 but also extends to cover along the side surfaces of the second chip 122, so that a direct contact area between the second chip 122 and the encapsulating layer 140 becomes even smaller, further enhancing stress relieving effect of the first buffer layer 130A′ on the second chip 122, thereby providing a better protection to the second chip 120.

Referring to FIG. 4, in yet other embodiments, the top surface of the first chip 121 is disposed with a second buffer layer 130B, and the top surface of the second chip 122 is disposed with the above-mentioned first buffer layer 130A. Some manufacturers require the light-emitting device 100 to undergo the aging process at a more stringent condition, which may aggravate the foregoing circumstances that cause an adverse effect on the light-emitting device 100. For instance, the first chip 121 may also face a risk of being pulled out. Accordingly, by covering the second buffer layer 130B on the top of the first chip 121 after disposing the first chip 121 within the functional section 113 of the first surface 1101 of the substrate 110 while prior to bonding the encapsulating layer 140, the first chip 121 and the encapsulating layer 140 may attain an incomplete contact. Hence, the second buffer layer 130B can play a role of relieving the stress of the first chip 121 during the aging process of the light-emitting device 100, thereby alleviating a risk of the first chip 121 being pulled out.

The second buffer layer 130B may have a refractive index not greater than a refractive index of the first chip 121 (ranging from 1.6 to 1.8) and not less than a refractive index of the encapsulating layer 140. For example, the second buffer layer 130B has the refractive index ranging from 1.3 to 1.6, and the encapsulating layer 140 has a refractive index ranging from 1.2 to 1.4. Therefore, as a light emitted from the first chip 121 sequentially passes through the second buffer layer 130B and the encapsulating layer 140, an effect resulting from a gradient refractive index may occur, thereby enhancing the brightness of the first chip 121.

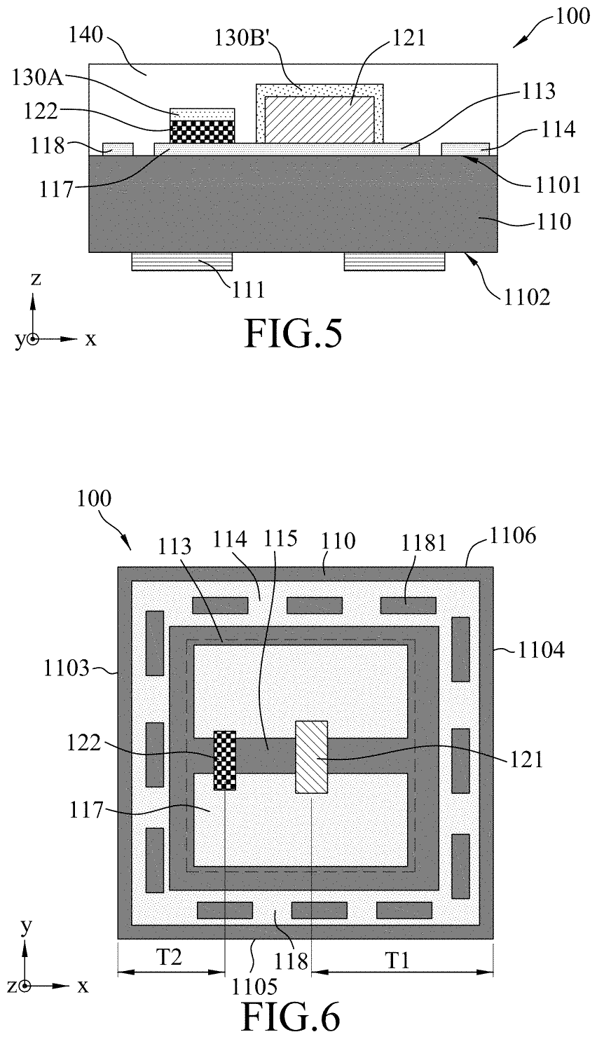

Referring to FIG. 5, in some embodiments, the second buffer layer 130B′ is disposed on the top surface of the first chip 121, and the first buffer layer 130A is disposed on the top surface of the second chip 122. The second buffer layer 130B′ not only covers the top surface of the first chip 121 but also extends to cover along the side surfaces of the first chip 121, thus further improving the protection of the second buffer layer 130B′ on the first chip 121.

Referring back to FIGS. 1 and 2, in this embodiment, the non-functional section 114 surrounds the functional section 113. In an exemplary embodiment, the light-emitting device 100 further includes a second metal layer 118 that is disposed on the non-functional section 114 of the first surface 1101 of the substrate 110. Moreover, a groove exists between the non-functional section 114 and the functional section 113 of the first surface 1101 of the substrate 110, so that the second metal layer 118 disposed on the non-functional section 114 can be isolated and insulated from the first metal layer 117 disposed on the functional section 113. In addition, the second metal layer 118 that is disposed on the non-functional section 114 may form a metal protrusion protruding from the first surface 1101 of the substrate 110, so as to enhance a bonding force between the encapsulating layer 140 and the substrate 110 and reduce a risk of the encapsulating layer 140 being separated from the edges of the substrate 110, thereby reducing a risk of the first and second chips 121, 122 being pulled out from the substrate 110.

Referring to FIG. 6, in an exemplary embodiment, the second metal layer 118 disposed on the non-functional section 114 is formed with a plurality of recesses 1181 using an etching method, which may further enhance the bonding force between the encapsulating layer 140 and the edges of the substrate 110.

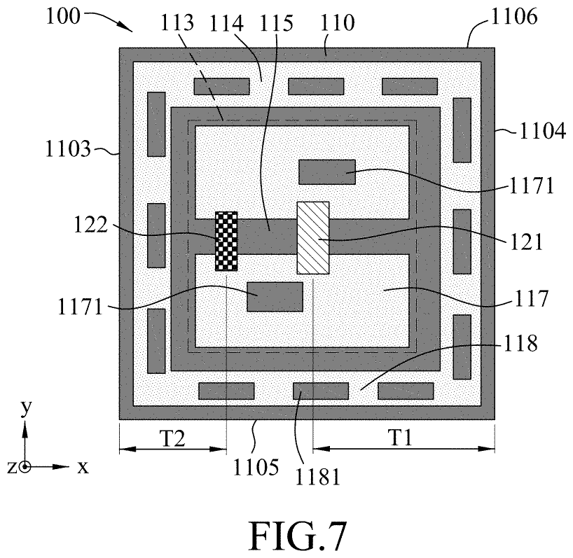

Referring to FIG. 7, in yet another exemplary embodiment, in order to further enhance the bonding force between the encapsulating layer 140 and the substrate 110, the first metal later 117 disposed on the functional section 113 is also formed with a plurality of recesses 1171.

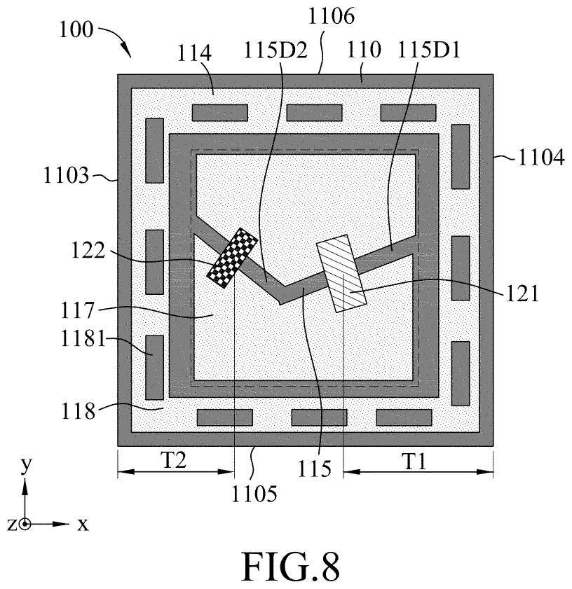

Referring to FIG. 8, in still some embodiments, the spacing 115 formed in the first metal layer 117 has a dimension with at least one corner, thereby dividing the spacing 115 into a first segment 115D1 and a second segment 115D2 around the at least one corner. The first and second segments 115D1, 115D2 are connected to but not aligned with each other. The first chip 121 is mounted on the first segment 115D1 of the spacing 115, and the second chip 122 is mounted on the second segment 115D2 of the spacing 115. The first chip 121 and the second chip 122 may be rotated by a certain angle for installation, so as to improve space utilization of the substrate 110, to reduce an absorption of light emitted from the side surfaces of the first chip 121 by the second chip 122 when the first chip 121 and the second chip 122 are disposed in parallel, and also to reduce a failure possibility of the second chip 122 which results from thermal and light radiation from the side surfaces of the first chip 121, thereby effectively enhancing the overall light emitting efficiency of the light-emitting device 100.

A second embodiment of the light-emitting device 100 according to the disclosure has a structure similar to that of the first embodiment, and the differences therebetween are described in detail below.

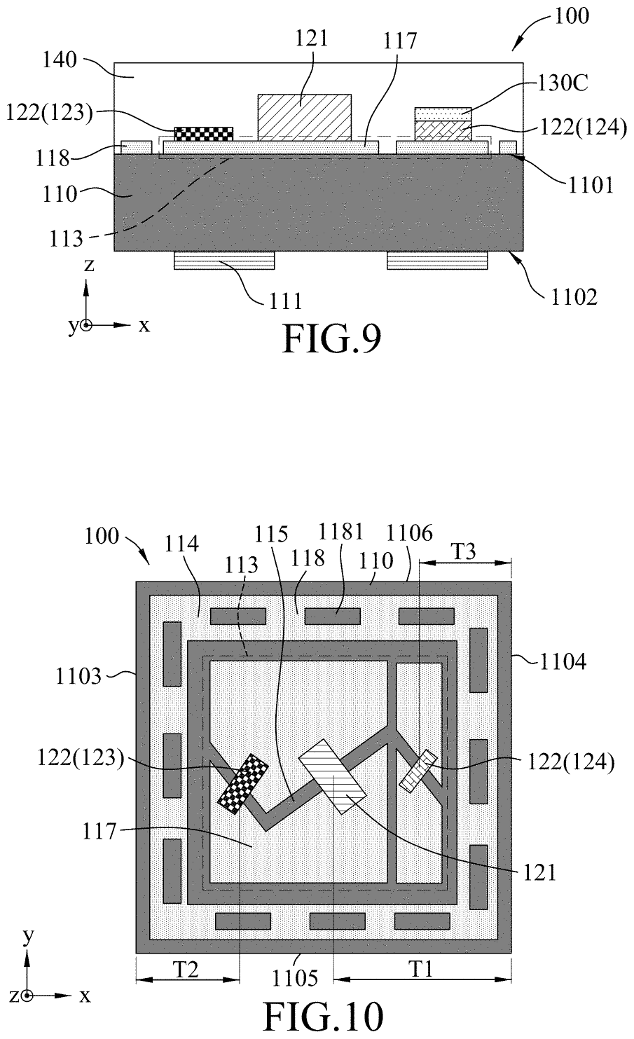

In this embodiment, the light-emitting device 100 includes a plurality of the second chips 122. A portion of the second chips 122 may be electrostatic discharge protection chips or may be any type of light-emitting chips that emit visible light. Referring to FIG. 9, the light-emitting device 100 of this embodiment according to the disclosure includes two second chips 122 one of which is an electrostatic discharge protection chip 123 and the other one is a light-emitting chip 124 that emits a visible light. To be specific, in an exemplary embodiment, the visible light has a wavelength which falls within a range of 380 nm to 740 nm. In another exemplary embodiment, the visible light has a wavelength which falls within a range of 380 nm to 420 nm, a range of 440 nm to 475 nm, a range of 490 nm to 570 nm, or a range of 625 nm to 740 nm.

Although not shown in detail, it is noted that the light-emitting chip 124 that emits the visible light as mentioned above may have a structure similar to that of the first chip 121, and details thereof are not repeated herein.

The functional section 113 of the first surface 1001 of the substrate 110 may be used to drive the first chip 121 and the light-emitting chip 124 to radiate light simultaneously. The first chip 121 and the light-emitting chip 124 may be connected to the functional section 113 either in series or parallel connection, so that the functional section 113 may be capable of turning on or off the first chip 121 and the light-emitting chip 124 synchronously. Hence, the first chip 121 may have the same working status as that of the light-emitting chip 124. When the light-emitting chip 124 starts working, the first chip 121 works as well by emitting the visible light, thereby fulfilling a purpose of identification.

In an exemplary embodiment, a plurality of the first chips 121 are present on the first surface 1001, and each of the first chips 121 is connected in series or parallel connection with at least one part of the light-emitting chip that emits the visible light so as to ensure that when each part of the first chip 121 is in a working status, at least one part of the light-emitting chip that emits the visible light is carrying out the function of identification and alarm.

Referring to FIG. 10, the second chips 122 (i.e., the electrostatic discharge protection chip 123 and the light-emitting chip 124) are respectively located within the functional section 113 which are more adjacent to the edges 1103, 1104 of the substrate 110 compared with the first chip 121. That is to say, the distance from the center point of first chip 121 to the edge 1104 of the substrate 110 in the first direction X (i.e., the first minimum distance T1) is greater than the distance from the center point of the light-emitting chip 124 to the edge 1104 of the substrate 110 in the first direction X (i.e., the second minimum distance T3). In addition, the distance from the center point of the first chip 121 to the edge 1104 of the substrate 110 in the first direction X (i.e., the first minimum distance T1) is greater than the distance from the center point of the electrostatic discharge protection chip 123 to the edge 1103 of the substrate 110 in the first direction X (i.e., the second minimum distance T2). In addition, the shortest distance from each of the center point of the foregoing chips to one of the edges of the substrate 100 is chosen for measurement.

It should be noted that, in the light-emitting device 100 shown in FIG. 10, the relationship of the first minimum distance T1, T1′ and second minimum distance T2, T2′ in the first direction X is illustrated. However, in some variations of the embodiments of the light-emitting device 100, the above-mentioned relationship can be applied in the second direction Y.

Referring to FIG. 9, in this embodiment, each of the first chip 121 and the second chip 122 has a thickness in the vertical direction Z, and the thickness of the first chip 121 is greater than that of the second chip 122. The thickness of the first chip 121 is greater than that of the light-emitting chip 124 by greater than or equal to 50 μm, for example, by a range of 50 μm to 200 μm. Moreover, the thickness of the first chip 121 is greater than that of the electrostatic discharge protection chip 123 by greater than or equal to 50 μm, for example, by a range of 100 μm to 300 μm.

Since the encapsulating layer 140 suffers from high temperature and high pressure during the manufacturing process, there may be a residual stress left inside of the encapsulating layer 140, which may cause the encapsulating layer 140 to release the residual stress, causing a crack occurring at the site where the residual stress stays during a long-term aging process, resulting in a warpage or a crack at the corner of the encapsulating layer 140, and even resulting in a separation of the encapsulating layer 140 and the substrate 110. As a result, the chips which are secured on the substrate 110 may be pulled out therefrom, consequently affecting the reliability of the light-emitting device 100.

Based on the above, referring again to FIG. 9, in this embodiment, the light-emitting chip 124 is formed with the top surface, the bottom surface opposite to the top surface, and the side surfaces that are connected to the top surface and the bottom surface. The top surface is more distant from the substrate 110 than the bottom surface. The top surface may be provided with a main light-emitting surface for emission of visible light. In addition, the first buffer layer 130C is disposed on the top surface of the light-emitting chip that emits the visible light. By covering the first buffer layer 130C on the top surface of the light-emitting chip 124 after disposing the light-emitting chip that emits the visible light within the functional section 113 of the first surface 1101 of the substrate 110 while prior to bonding the encapsulating layer 140, the contact area between the light-emitting chip 124 and the encapsulating layer 140 can be reduced, so that the first buffer layer 130C can be of service to the light-emitting chip 124 by relieving the residual stress released during the aging process of the encapsulating layer 140, thereby reducing the risk of the light-emitting chip 124 being pulled out.

The first buffer layer 130C may be made of a material selected from the group consisting of silicone rubber, epoxy resin, perfluoropolyether, and a combination thereof, but is not limited thereto. For example, the first buffer layer 130C may be made of silicone rubber covering on the top surface of the light-emitting chip that emits the visible light by means of dispensing, and an amount of silicone rubber used is determined based on a desired thickness. In certain embodiments, the first buffer layer 130C has a thickness ranging from 10 μm to 200 μm. If the thickness of the first buffer layer 130A′ is less than 10 μm, there may have less effect on stress buffering. In addition, if the thickness of the first buffer layer 130C is greater than 200 μm, instead of achieving the buffering effect, the encapsulating layer 140 may be prone to cracking. In an exemplary embodiment, the first buffer layer 130C has a thickness ranging from 10 μm to 50 μm.

In other embodiments, the first buffer layer 130C is made of the material, such as silicone rubber or epoxy resin, containing a wavelength converting substance, which may convert a color shown by the light-emitting chip 124 as desired. Specifically, the wavelength converting substance may be a material such as phosphor powder that is uniformly distributed in the first buffer layer 130C.

Furthermore, the first buffer layer 130C has a refractive index ranging from 1.3 and 1.6, and the encapsulating layer 140 has a refractive index ranging from 1.2 and 1.4. Therefore, an emitted light may pass through the first buffer layer 130A′ and the encapsulating layer 140, both of which form a gradient refractive index, thereby enhancing the brightness of the light-emitting chip 124.

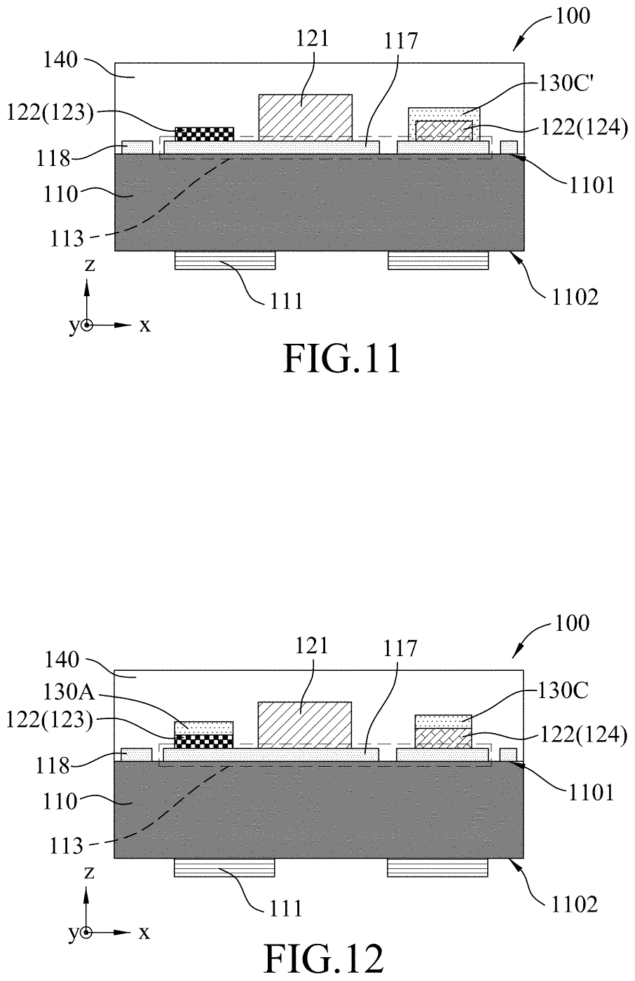

Referring to FIG. 11, in other embodiments, the first buffer layer 130C′ not only covers the top surface of the light-emitting chip 124 but also extends to cover along the side surfaces of the light-emitting chip 124, so that the direct contact area between the light-emitting chip 124 and the encapsulating layer 140 becomes even smaller, further improving protection offered by the first buffer layer 130C′ to the light-emitting chip 124.

Referring to FIG. 12, in yet other embodiments, the first buffer layer 130A is disposed on the top surface of the electrostatic discharge protection chip 123, and the first buffer layer 130C is disposed on the top surface of the light-emitting chip 124. By covering the first buffer layer 130A on the top surface of the electrostatic discharge protection chip 123 after disposing the electrostatic discharge protection chip 123 within the functional section 113 of the first surface 1101 of the substrate 110 while prior to bonding the encapsulating layer 140, a contact area between the electrostatic discharge protection chip 123 and the encapsulating layer 140 can be reduced, so that the first buffer layer 130A can be of service to the electrostatic discharge protection chip 123 by relieving the residual stress released during the aging process of the light-emitting device 100, thereby reducing the risk of the electrostatic discharge protection chip 123 being pulled out.

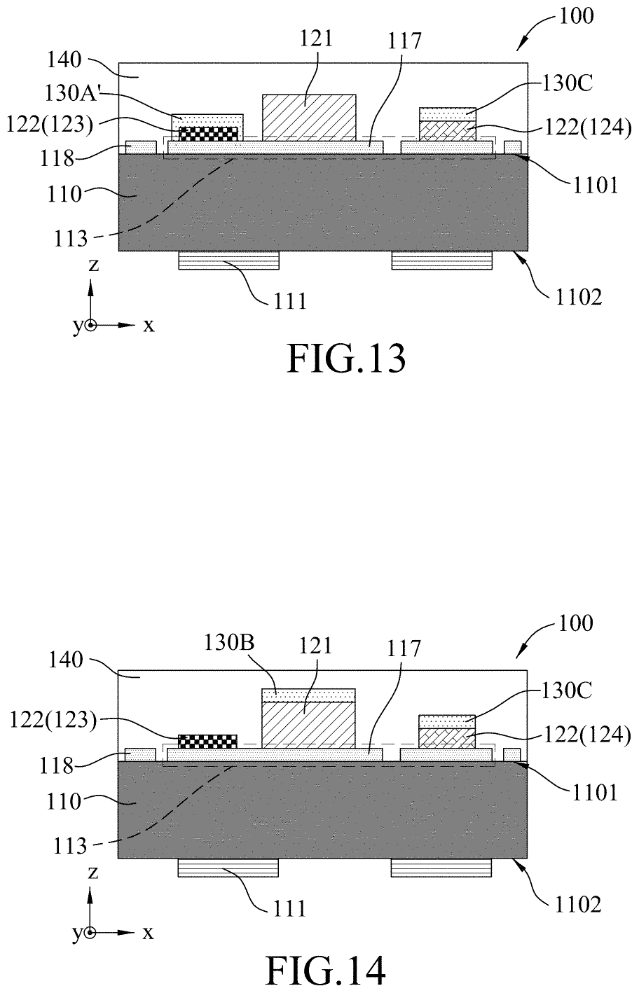

Referring to FIG. 13, in yet other embodiments, the first buffer layer 130A′ not only covers the top surface of the electrostatic discharge protection chip 123 but also extends to cover along the side surfaces of the electrostatic discharge protection chip 123, so that the direction contact area between the electrostatic discharge protection chip 123 and the encapsulating layer 140 becomes even smaller, further enhancing stress relieving effect of the first buffer layer 130A′ on the electrostatic discharge protection chip 123, thereby providing a better protection to the electrostatic discharge protection chip 123.

Referring to FIG. 14, in still yet other embodiments, the second buffer layer 1308 is disposed on the top surface of the first chip 121, and the first buffer layer 130C is disposed on the top surface of the light-emitting chip that emits visible light. Some manufacturers require the light-emitting device 100 to undergo the aging process at a more stringent condition, which may aggravate the above-mentioned circumstances that cause an adverse effect on the light-emitting device 100. For example, the first chip 121 may also be at risk of being pulled out. As a result, by covering the second buffer layer 1308 on the top surface of the first chip 121 after disposing the first chip 121 within the functional section 113 of the first surface 1101 of the substrate 110 while prior to bonding the encapsulating layer 140, the contact area between the first chip 121 and the encapsulating layer 140 can be reduced, so that the second buffer layer 1308 can be of service to the first chip 121 by relieving the residual stress released during the aging process of the light-emitting device 100, thereby reducing the risk of the first chip 121 being pulled out.

Furthermore, the second buffer layer 130B has a refractive index ranging from 1.3 and 1.6, and the encapsulating layer 140 has a refractive index ranging from 1.2 and 1.4. Therefore, an emitting light may pass through the second buffer layer 1308 and the encapsulating layer 140 to form a graded refractive index, thereby enhancing the brightness of the first chip 121.

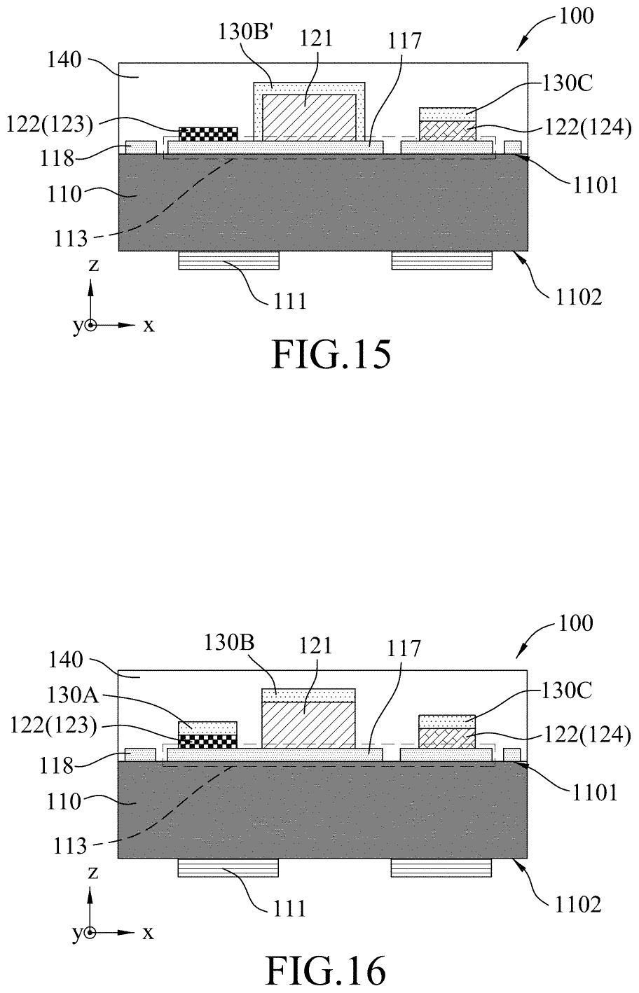

Referring to FIG. 15, in some embodiments, the second buffer layer 130B′ is disposed on the first chip 121, and first buffer layer 130C is disposed on the top surface of the light-emitting chip that emits the visible light. The second buffer layer 130B′ not only covers the top surface of the first chip 121 but also extends to cover along the side surfaces of the first chip 121, further enhancing the protection of the second buffer layer 130B′ on the first chip 121.

Referring to FIG. 16, in yet some embodiments, the first buffer layer 130A is disposed on the top surface of the electrostatic discharge protection chip 123, the second buffer layer 130B is disposed on the top surface of the first chip 121, and the first buffer layer 130C is disposed on the top surface of the light-emitting chip 124.

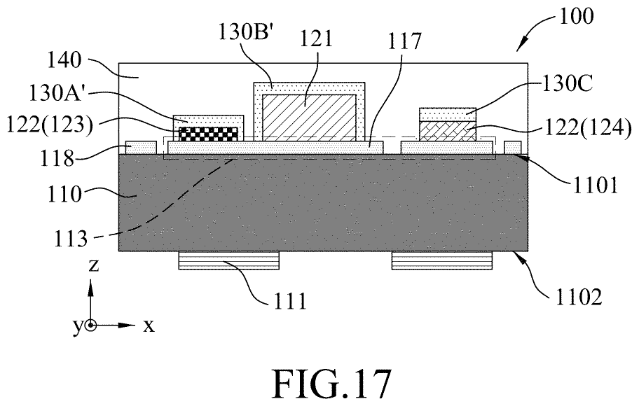

Referring to FIG. 17, in still yet some embodiments, the first buffer layer 130A′ is disposed on the electrostatic discharge protection chip 123, the second buffer layer 130B′ is disposed on the first chip 121, and the first buffer layer 130C is disposed on the top surface of the light-emitting chip 124. The first buffer layer 130A′ not only covers the top surface of the electrostatic discharge protection chip 123 but also extends to cover along the side surfaces of the electrostatic discharge protection chip 123. The second buffer layer 130B′ not only covers the top surface of the first chip 121 but also extends to cover along the side surfaces of the first chip 121, thereby further enhancing the protection of the first buffer layer 130A′ and the second buffer layer 130B′ to the electrostatic discharge protection chip 123 and the light-emitting chip 124, respectively.

In summary, the light-emitting device 100 according to the disclosure has the following advantageous effects:
(1) By disposing the first buffer layer 130A, 130A′, 130C, 130C′ on the top surface of at least one part of the second chip 122, the contact area between the second chip 122 and the encapsulating layer 140 can be reduced, so that the first buffer layer 130A, 130A′, 130C, 130C′ can be of service to the second chip 122 by relieving the residual stress remaining in the encapsulating layer 140 released during the aging process of the light-emitting device 100, so as to reduce the risk of the second chip 122 being pulled out, thereby improving the reliability of the light-emitting device 100.
(2) The first buffer layer 130A, 130A′, 130C, 130C′ is disposed on the top surface of at least one part of the second chip 122, namely, the second chip 122 is disposed with both the first buffer layers 130A, 130A′, 130C, 130C′ and the encapsulating layer 140, which are presented with a gradient refractive index. When the second chip 122 is designed to emit visible light, the brightness of the second chip 122 can be increased.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A light-emitting device, comprising:
a substrate including a first surface and a second surface opposite to said first surface, said first surface extending along a first direction and a second direction intersecting the first direction;
a first chip disposed on said first surface of said substrate, and including a first type semiconductor layer, a second type semiconductor layer, and an active layer that is interposed between said first type semiconductor layer and said second type semiconductor layer and that is configured to emit a light;
a second chip disposed on said first surface of said substrate, and formed with a top surface, a bottom surface opposite to said top surface, and a plurality of side surfaces that are connected to said top surface and said bottom surface;
a first buffer layer disposed on said top surface of said second chip so as to relieve stress; and
an encapsulating layer made of fluorine-containing resin and disposed on said first surface of said substrate to allow said first chip, said first buffer layer and said second chip to be encapsulated between said substrate and said encapsulating layer,
wherein said substrate has two edges spaced apart from each other in one of said first direction and said second direction, said first chip having a first minimum distance distant from one of said two edges in one of said first direction and said second direction, said second chip having a second minimum distance distant from one of said two edges in a corresponding one of said first direction and said second direction, said first minimum distance being greater than said second minimum distance.

2. The light-emitting device as claimed in claim 1, wherein said first buffer layer further covers said side surfaces of said second chip.

3. The light-emitting device as claimed in claim 1, wherein said first buffer layer has a thickness ranging from 10 μm to 200 μm.

4. The light-emitting device as claimed in claim 3, wherein said thickness of said first buffer layer ranges from 10 μm to 50 μm.

5. The light-emitting device as claimed in claim 1, wherein said first buffer layer is made of a material selected from the group consisting of silicone rubber, epoxy resin, perfluoropolyether, and combinations thereof.

6. The light-emitting device as claimed in claim 1, wherein said first chip emits the light having a wavelength which falls within a range of 200 nm to 380 nm or a range of 780 nm to 1000 nm.

7. The light-emitting device as claimed in claim 1, wherein said light-emitting device includes a plurality of said second chips, a portion of said second chips being light-emitting chips that emit visible light.

8. The light-emitting device as claimed in claim 7, wherein said visible light has a wavelength which falls within a range of 380 nm to 420 nm, a range of 440 nm to 475 nm, a range of 490 nm to 570 nm, or a range of 625 nm to 740 nm.

9. The light-emitting device as claimed in claim 1, wherein said second chip is an electrostatic discharge protection chip.

10. The light-emitting device as claimed in claim 1, wherein said first surface of said substrate has a functional section, said first and second chips being located within said function section, and
wherein said light-emitting device further comprises a first metal layer that is disposed on said functional section of said first surface and between said first and second chips and said first surface of said substrate, said first metal layer being formed with a spacing to form two electrical isolation areas.

11. The light-emitting device as claimed in claim 10, wherein said first metal layer is formed with a recess.

12. The light-emitting device as claimed in claim 10, wherein said first surface of said substrate has a non-functional section that surrounds said functional section,
wherein said light-emitting device further comprises a second metal layer that is disposed on said non-functional section of said first surface of said substrate.

13. The light-emitting device as claimed in claim 12, wherein said second metal layer is formed with a recess.

14. A light-emitting device, comprising:
a substrate including a first surface and a second surface opposite to said first surface, said first surface defining a vertical direction perpendicular thereto;
a first chip disposed on said first surface of said packaging substrate, and including a first type semiconductor layer, a second type semiconductor layer, and an active layer that is interposed between said first type semiconductor layer and said second type semiconductor layer and that is configured to emit a light;
a second chip disposed on said first surface of said substrate, and formed with a top surface, a bottom surface opposite to said top surface, and a plurality of side surfaces that are connected between said top surface and said bottom surface,
a first buffer layer disposed on said top surface of said second chip so as to relieve stress; and
an encapsulating layer made of fluorine-containing resin and disposed on said first surface of said substrate to allow said first chip, said first buffer layer and said second chip to be encapsulated between said substrate and said encapsulating layer,
wherein each of said first chip and said second chip has a thickness in said vertical direction, and said thickness of said first chip is greater than that of said second chip.

15. The light-emitting device as claimed in claim 14, wherein said first buffer layer further covers said side surfaces of said second chip.

16. The light-emitting device as claimed in claim 14, wherein said thickness of said first chip is greater than that of said second chip by not less than 50 μm.

17. The light-emitting device as claimed in claim 16, wherein said thickness of said first chip is greater than that of said second chip by a range of 50 μm to 300 μm.

18. The light-emitting device as claimed in claim 14, wherein said first surface extends along a first direction and a second direction intersecting said first direction, both the first and second directions being perpendicular to the vertical direction, and
wherein said substrate has first and second edges spaced apart from each other in one of said first direction and said second direction, said first chip disposed adjacent to said first edge, and said second chip disposed adjacent to said second edge,
wherein said first chip is distant from said first edge by a first minimum distance, said second chip being distant from said second edge by a second minimum distance, and said first minimum distance being greater than said second minimum distance.

19. The light-emitting device as claimed in claim 14, wherein said first chip is configured to emit an invisible light, and
wherein said light-emitting device includes a plurality of said second chips, a portion of said second chips being light-emitting chips that emit visible light.

20. The light-emitting device as claimed in claim 14, wherein said first chip is configured to emit an invisible light, and
wherein said light-emitting device includes a plurality of said second chips, a portion of said second chips being electrostatic discharge protection chips.
